(19) United States
(12) Patent Application Publication
(10) Pub. No.: US 2007/0121392 A1
(43) Pub. Date: May 31, 2007

(54) Nonvolatile semiconductor memory device and its writing method

(75) Inventor: Masaru Nawaki, Nara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/607,633

(22) Filed: Nov. 30, 2006

(30) Foreign Application Priority Data
Nov. 30, 2005 (JP) 2005-345638

(51) Int. Cl. G11C 7/00

(52) U.S. Cl. 365/191

(57) ABSTRACT

There is provided a nonvolatile semiconductor memory device and its writing method capable of controlling an increase in threshold voltage due to effects of adjacent memory cells and performing stable readout operations even if miniaturization of semiconductor memory devices proceeds further. The device comprises a memory cell array 411 having memory cells in a row and column directions, a row selection circuit 412, a column selection circuit 411, and a control circuit 405 for exercising writing control on a selected memory cell by an external command input. The control circuit performs a threshold voltage control for writing a memory cell selected as a writing target to a first predetermined threshold voltage when receiving a first external write command, and performs another threshold voltage control for writing the selected memory cell to a second predetermined threshold voltage different from the first threshold voltage when receiving a second external write command.

### CROSS REFERENCE TO RELATED APPLICATION

This Nonprovisional application claims priority under 35 U.S.C. § 119(a) on patent application No. 2005-345638 filed in Japan on 30 Nov., 2005, the entire contents of which are hereby incorporated by reference.

### BACKGROUND OF THE INVENTION

1. Field of the Invention

The present invention relates to a semiconductor memory device and specifically to a nonvolatile semiconductor memory device and a method of writing data thereto.

2. Description of the Related Art

As a nonvolatile semiconductor memory device (hereinafter referred to a nonvolatile memory) represented by a flash memory does not lose saved data even when the power is turned off, it is widely used in all products ranging from digital mobile devices such as a cellular phone, digital camera, portable music player, etc., to networking equipment such as a digital TV, set top box, or a router, etc., and is expected to find widespread applications in the future. In particular, in the case of a cellular phone or a digital camera, as the number of built-in application software programs increases and image resolution improves, demand for memory storage capacity is rising every year. Thus, as higher-capacity nonvolatile memory is demanded, many nonvolatile memory manufacturers tackle the challenges of supply of high-capacity memory and cost reduction through miniaturization.

In recent years, in particular, has been developed what is referred to as a multilevel memory that stores 2 bits in one memory cell of a flash memory. In a flash memory, although data is written by changing threshold voltage of a memory cell transistor, in such a multilevel memory, one memory cell can store twice as much data as usual. Thus, when data is written into a memory cell, a highly sophisticated writing control is performed so that there will be less deviation of post-writing threshold voltage from predetermined threshold voltage. However, in line with reduction of memory cell size due to the miniaturization trend in recent years, as data is often written into one memory cell, and then into memory cells adjacent to that memory cell, a risk that threshold voltage that has been once written and set will suffer from a deviation due to effects of the adjacent memory cells, and thereby read-out margins gradually will worsen has been pointed out. In the following, we describe the risk in more details referring to the related art.

To describe the related art, herein we use as an example NOR type flash memory that is widely used in a cellular phone, etc. FIG. 11 and FIG. 12 show sections of one memory cell of a NOR type flash memory. FIG. 11 is a sectional view taken along a bit line, and FIG. 12 is a sectional view taken along a word line. As shown in FIG. 11, a memory cell consists of a word line (control gate, hereinafter referred to as CG) 101, an insulating film 102 generally referred to as an ONO film, a floating gate (hereinafter referred to as FG) 103 for accumulating an electric charge, an insulating film 104 referred to as a tunnel film for exchanging electrons when electrons are injected into the FG 103 or extracted from the FG 103 during writing or erasing, a substrate 105, a drain 106 of a memory cell configured by diffusion, a contact 107 for electrically connecting the drain 106 and a bit line (not shown), and a source 108 of the memory cell configured by diffusion. In addition, as shown in FIG. 12, among respective memory cells is formed trench isolation 110 for separating a diffused layer (drain).

When writing a memory cell, apply high voltage (approximately 5 to 12 volts) to CG 101, voltage of approximately 3 to 5 volts to the drain 106, and 0V to the source 108 and the substrate 105, respectively. Electrons flowing out of the source 108 into the drain 106 are accelerated in the vicinity of the drain 106, generating hot electrons. With an electric field generated by the high voltage of the CG 101, a part of the hot electrons go beyond a barrier of the tunnel film 104, and are injected into the FG 103. Therefore, when writing takes place, the electrons are injected into the FG 103, thus decreasing voltage of FG 103, and a threshold voltage of the memory cell increases. Reversely, to erase a memory cell, generate electric fields in the substrate 105 and FG 103 by applying high voltage of approximately 5 to 9 volts to the substrate 105, and thus negative voltage of approximately −5 to −7 volts to CG 101. Then, electrons are discharged by tunnel current from FG 103 to the substrate 105 by way of the tunnel film 104. This decreases electrons from FG 103, thereby increasing the voltage of FG 103 and decreasing the threshold voltage of the memory cell.

In the following, we describe behavior of threshold voltage of a memory cell during writing. FIG. 13 shows distribution of threshold voltage of a binary NOR type flash memory. In a flash memory, a collection of memory cells of 1 Mbit or 2 Mbits is generally treated as a block (or alternatively referred to as a sector), and all memory cells are erased as a block. In the figure, 211 shows distribution of threshold voltage of erased memory cells, and erasing is performed till it falls below a predetermined erasing threshold voltage 213. If writing is made into the erased memory cells, the threshold voltage of the memory cells rise, as described above. As can be seen from the threshold voltage distribution 212 of the written memory cells, writing is executed so that the threshold voltage will exceed the preset writing threshold voltage 215. The voltage 214 is a threshold voltage to serve as a reference when reading takes place, and is set between the erasing threshold voltage 213 and the writing threshold voltage 215. Voltage differences 217 and 218 represent a difference between the erasing threshold voltage 213 and the reference voltage 214, and between the writing threshold voltage 215 and the reference voltage 214, respectively. The greater the voltage difference is, the wider the readout margin is, thereby enabling stable and fast readout. Width of the writing threshold voltage distribution 219 signifies that last threshold voltage during wiring fluctuates. In the case of a binary flash memory, basically, even if the width of the threshold voltage 219 widens, there will arise no operational problem as far as the voltage differences 217 and 218 are kept sufficiently wide.

FIG. 14 shows threshold voltage distribution of a NOR-type multilevel flash memory (in this case, a four-level flash memory). In FIG. 14 are shown the threshold voltage distribution of erased memory cells 221, and that of written memory cells, 222, 223, 224. Three kinds of reference threshold voltages for readout 225, 226, and 227 are needed to determine four kinds of threshold voltages, respectively, during readout. Thus, the threshold voltage distribution 222 must be present inner than the reference voltages 225 and 226, and the threshold voltage distribution 223 must be present inner than the reference voltages 226 and 227. Thus, to ensure adequate readout margin, compared with a binary memory, in a multilevel memory, writing should be done so that width of the writing threshold voltage distribution 228, 229 will be sufficiently narrow. In a memory that is actually commercially available, the width of threshold voltage distribution of the binary flash memory 219 and that of a multilevel flash memory 228 (229 is also same) are approximately 1.2 V and 300 mV, respectively.

Next, FIG. 15 and FIG. 16 show a plurality of memory cells of FIG. 11 and FIG. 12 that are arranged in accordance with an actual memory array. As shown in FIG. 15 and FIG. 16, on the substrate 305 are respectively formed CGs 301, 311, ONO films 302, 312, 332, 342, FGs 303, 313, 333, 343, tunnel films 304, 314, 334, 344, and contacts 307, 317, similar to FIG. 11 and FIG. 12, wherein drains 306, 316, source 308, and isolation 310 are formed in the substrate 305. The memory cell 322 neighbors the memory cell 321 with the source 308 sandwiched therebetween, and the memory cell 321 has the memory cells 351 and 352 on both adjacent sides with the isolation 310 sandwiched therebetween.

Then, focusing on the memory cell 321, we describe effects of the adjacent cells when writing takes place. FG 303 of the memory cell 321 is capacitively coupled by parasitic capacitance 361 to 367 with CG 301, the substrate 305, the drain 306, the source 308, FG 313 of the adjacent memory cell, FG 333 of the adjacent memory cell, and FG 343 of the adjacent memory cell, respectively.

Now, consider the case in which writing is performed into the memory cell 321 to change it into the state 222 of FIG. 14 and then into the adjacent memory cells 322, 351, 352 to change them into the state 224 of FIG. 14. First, to write into the memory cell 321, electrons are injected into FG 303 to decrease voltage of FG. Upon completion of writing, voltage of FG 303 is stabilized. Writing should be performed carefully so that threshold voltage distribution after writing can be fitted in the distribution 222 of FIG. 14. Then, to write into the adjacent memory cells 322, 351, 352, electrons are injected into FGs 313, 333, 343 of the respective memory cells, resulting in reduced voltage thereof. As FG 303 of the memory cell 321 is physically opposed to the respective FGs 313, 333, 343 of the adjacent memory cells 322, 351, 352, it is capacitively coupled by capacitance 365, 366, 367. Thus, when voltages of FGs 313, 333, 343 decrease, the voltage of FG 303 of the memory cell 321 will fall because of capacitive couplings 365, 366, 367, and then the threshold voltage of the memory cell 321 will rise above the first written value.

If such writing is performed in the entire the memory cell array, due to effects of increased the threshold voltage of the memory cell into which writing is performed later, the distribution 222 of FIG. 14 approaches to the high side of the threshold voltage, in other words, it is shifted to the right side and comes close to the readout reference voltage 226. Then, readout margin worsens, and readout error may occur in the worst case. As miniaturization progresses, a space with the adjacent memory cells will be further narrowed, and thus coupled capacitance 365, 366, 377 of FGs with adjacent memory cells will grow relative to other capacitance 361, 362, 363, 364. Thus, the threshold voltage of the cell when writing is performed into the adjacent memory cells will further increase and worsen the readout margin, thus causing a major obstacle of miniaturization.

As a technique to eliminate such the effects of the adjacent memory cells, a pre-writing/post-writing approach is proposed. (For instance, see Japanese Patent Application Laid-Open No. 2005-25898, which is hereinafter referred to the known publication.) FIG. 17 shows an embodiment thereof. Now, in order to avoid an increase in threshold voltage due to capacitive coupling among floating gates between adjacent bit lines, first, pre-writing is performed to memory cells of even column BL2j (where j is an integer greater than 0). When writing to memory cells of the even columns, allowing, in advance, for possible increase in threshold voltage of memory cells that the capacitive coupling is expected to affect when writing is performed to memory cells in the odd columns, writing is performed to a threshold voltage lower than the final writing threshold voltage. Then, after performing post-writing to memory cells in the odd column BL2j+1, based on result of reading out respective memory cells in the even column to which pre-writing has been done, additional writing is performed again to the memory cells in the even column not affected by writing to the memory cells in the odd columns. When performing post-writing to the memory cells in the odd columns, writing is performed to the final writing threshold voltage because there is little effect of the memory cells in the even columns. FIG. 18 and FIG. 19 show variations of the threshold voltage in this case. Use of such the approach could eliminate effects of variations in the threshold voltage from memory cells adjacent in the bit line direction.

However, there exist two problems in the technology of the known publication. The first problem is that effects of memory cells on adjacent word lines cannot be alleviated, while effects of memory cells on adjacent bit lines can be eliminated. For instance, if we write to a memory cell connected to the word line WL2 after writing to a memory cell connected to the word line WL1 in FIG. 17, the threshold voltage of memory cells connected to the word line WL1 will also rise. In particular, in the NAND type flash memory used in the embodiment shown in the known publication, increase in the threshold voltage will be more remarkable because a space between the word lines is narrower than the NOR type flash memory.

The second problem is that in order to perform writing as described in the known publication, writing data of when pre-writing is done to the even columns should be continuously retained in a latch circuit even when post-writing is done to the odd columns. This is because it is necessary to perform additional writing again to the memory cells of the even columns that are not affected by writing to the odd columns after writing to the memory cells in the odd columns is complete, since writing is done to threshold voltage lower than the final writing threshold voltage in the pre-writing to the memory cells in the even column. As the number of columns increases, latch circuits will also be needed accordingly, thus leading to expansion of chip area.

### SUMMARY OF THE INVENTION

The present invention has been made in view of the above problems, and its object is to provide a nonvolatile semiconductor memory device capable of controlling an increase in threshold voltage due to effects of adjacent memory cells and performing stable readout operations, even if miniaturization of semiconductor memory devices proceeds further. It is another object to provide a method of writing data into such a nonvolatile semiconductor memory device.

In order to achieve the above objects, a nonvolatile semiconductor memory device according to the present invention is characterized as a first feature by comprising a memory cell array consisting of memory cells having a nonvolatile transistor capable of electrically writing, erasing and reading out information arranged in a matrix in a row direction and in a column direction, a row selection circuit for selecting the memory cell in the row direction, a column selection circuit for selecting the memory cell in the column direction, and a control circuit for exercising a writing control on the memory cell selected by the row selection circuit and the column selection circuit by a command inputted from outside, wherein the control circuit is configured to be able to receive a first external write command and a second external write command, and when receiving the first external write command, the control circuit performs the first threshold voltage control for writing the memory cell selected as a writing target to a first predetermined threshold voltage, and when receiving the second external write command, performs the second threshold voltage control for writing the memory cell selected as a writing target to a second predetermined threshold voltage that is different from the first threshold voltage.

The nonvolatile semiconductor memory device having the above characteristics has a second characteristic that the second threshold voltage is set within a predetermined range from a value derived from adding a variation of a threshold voltage to the first threshold voltage, and the variation of a threshold voltage is of the memory cell already written by the first threshold voltage control and caused by writing subsequently an adjacent memory cell.

The nonvolatile semiconductor memory device having any of the characteristics as described above has a third characteristics that the first threshold voltage control is conducted by applying a writing pulse based on a current comparison between the memory cell to be written and a first reference memory cell, and the second threshold voltage control is conducted by applying a writing pulse based on a current comparison between the memory cell to be written and a second reference memory cell.

The nonvolatile semiconductor memory device of the first or second characteristic has a fourth characteristic that the first and second threshold voltage controls are conducted by using a same reference memory cell, and applying different gate voltages between the first and second threshold voltage controls to a control gate of the memory cell or the reference memory cell.

A method of writing to the nonvolatile semiconductor memory device according to the present invention to achieve said objects has a fifth characteristic that in the semiconductor memory device having any of the characteristics described above, writing is performed by the first external write command to a plurality of the memory cells selected as a writing target in the memory cell array, and furthermore, writing is performed by the second external write command to the plurality of memory cells in the memory cell array written by the first external write command.

The nonvolatile semiconductor memory device having the above characteristics has a sixth characteristic that an address and data of the memory cell to be written by the second external write command are the same as an address and data of the memory cell written by the first external write command.

According to the present invention, the control circuit is configured such that when receiving the first external write command, the control circuit performs the first threshold voltage control for writing the memory cell selected as a writing target to the predetermined first threshold voltage, and that when receiving the second external write command, performs the second threshold voltage control for writing the memory cell selected as a writing target to the predetermined second threshold voltage that is different from the first threshold voltage, wherein if the second threshold voltage is set within a predetermined range from a value derived from adding a variation of a threshold voltage to the first threshold voltage and the variation of a threshold voltage is of the memory cell already written by the first threshold voltage control and caused by writing subsequently an adjacent memory cell, as shown in FIG. 20, when the first external write command is received, threshold voltage distribution as a whole is lower than the threshold voltage distribution 412, 413 of the conventional art with no measures, and distributed as the threshold voltage distribution 415. Then, although writing is performed to memory cells (memory cells in the threshold voltage distribution 417) having lower threshold voltage than a voltage Vtr2 by using the second external command, then the threshold voltage distribution after writing by the second external command of the memory cells having lower threshold voltage than the voltage Vtr2 will be like the threshold voltage distribution 418, because distribution of the memory cells that will be a target of writing and that of adjacent memory cells thereof are located in adjacent positions. Furthermore, due to disturbance in writing, the threshold voltage distribution 415 will be threshold voltage distribution 416 and the threshold volt distribution 418 will be threshold voltage distribution 419. However, as any threshold voltage distribution does not distribute beyond a threshold voltage Vtr3, and thus threshold voltage of respective memory cells can be distributed in the range of the threshold voltage distribution 412 of when no disturbance in writing occurs.

This could not only make it possible to prevent threshold voltage distribution from being diffused due to effects of adjacent memory cells, first by using the first external write command and writing data into all memory cells to be affected by capacitive coupling from adjacent memory cells, and then by using the second external write command and writing the same data as that written by using the first external write command to the same address to which writing is performed by using the first external write command, but also eliminate the need for retaining in the nonvolatile memory much data to be written since an external writing system such as PROM writer, for example, can be used by using respective external commands when writing data, thereby enabling control of increased chip area.

### BRIEF DESCRIPTION OF THE DRAWINGS

FIG. 1 is a schematic circuit block diagram showing one configuration example of a nonvolatile semiconductor memory device according to the present invention;

FIG. 2 is a circuit diagram showing one configuration example of a sense amplifier of a nonvolatile semiconductor memory device according to the present invention;

FIG. 3 is a circuit diagram showing one configuration example of a reference circuit of a nonvolatile semiconductor memory device according to the present invention;

FIG. 4 is a graph showing voltage properties of a reference cell to be used in the reference circuit of the nonvolatile semiconductor memory device according to the present invention;

FIG. 5 is a circuit diagram showing one configuration example of a write voltage generation circuit of a nonvolatile semiconductor memory device according to the present invention;

FIG. 6 is a flow chart showing one embodiment of a method of writing to a nonvolatile semiconductor memory device according to the present invention;

FIG. 7 is a flow chart showing one embodiment of a writing algorithm by a first external write command in a method of writing to a nonvolatile semiconductor memory device according to the present invention;

FIG. 8 is a flow chart showing one embodiment of a writing algorithm by a second external write command in a method of writing to a nonvolatile semiconductor memory device according to the present invention;

FIG. 9 is a circuit diagram showing a configuration example of a reference circuit of other nonvolatile semiconductor memory device according to the preset invention;

FIG. 10 is a graph showing voltage properties of the reference cells to be used in other configuration examples of a reference circuit according to a nonvolatile semiconductor memory device according to the present invention;

FIG. 11 is a cross sectional view showing memory cell structure of a semiconductor memory device according to the prior art;

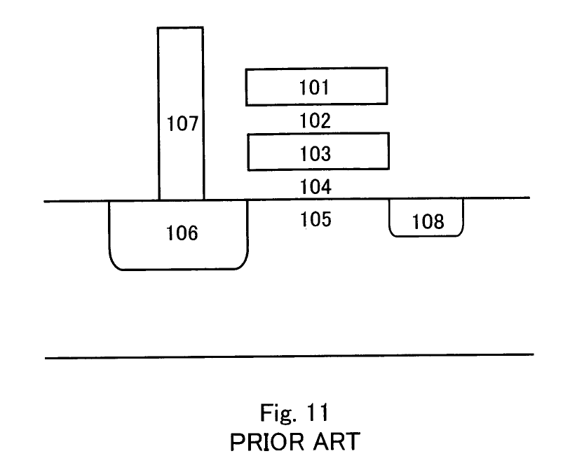

FIG. 12 is a cross sectional view showing memory cell structure of a semiconductor memory device according to the prior art;

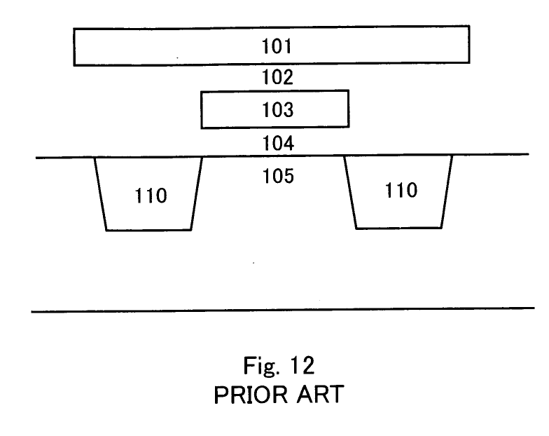

FIG. 13 is a graph showing threshold voltage distribution of binary memory cells of a nonvolatile semiconductor memory device according to the prior art;

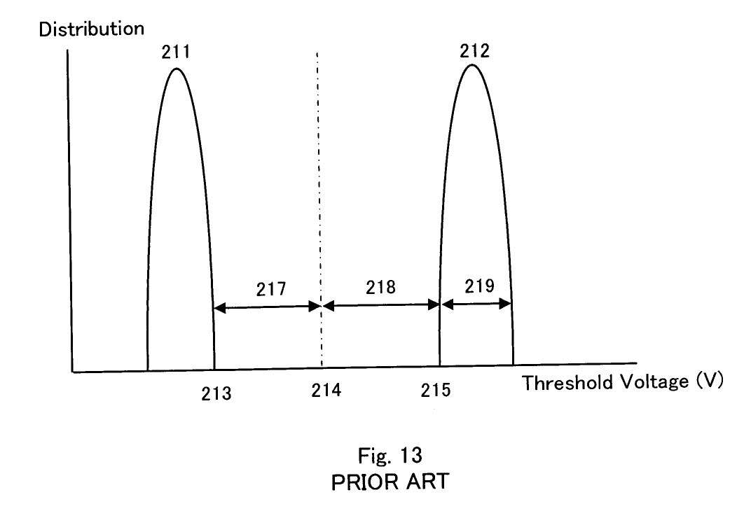

FIG. 14 is a graph showing threshold voltage distribution of four-level memory cells of a nonvolatile semiconductor memory device according to the prior art;

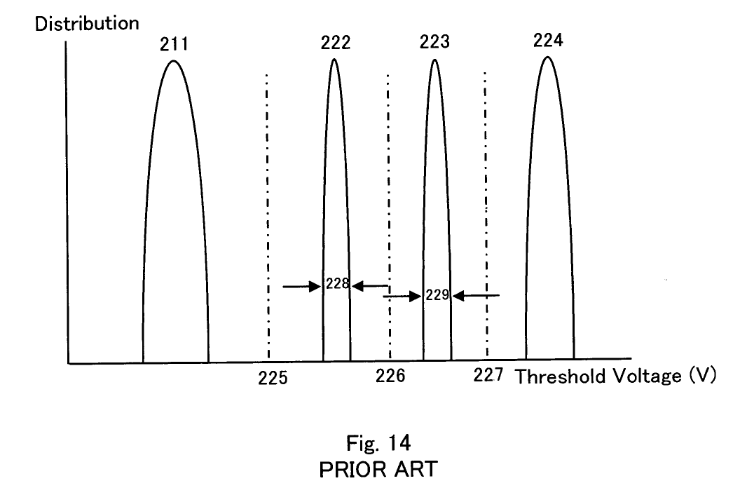

FIG. 15 is a sectional view of memory cell array structure of a semiconductor memory device according to the prior art;

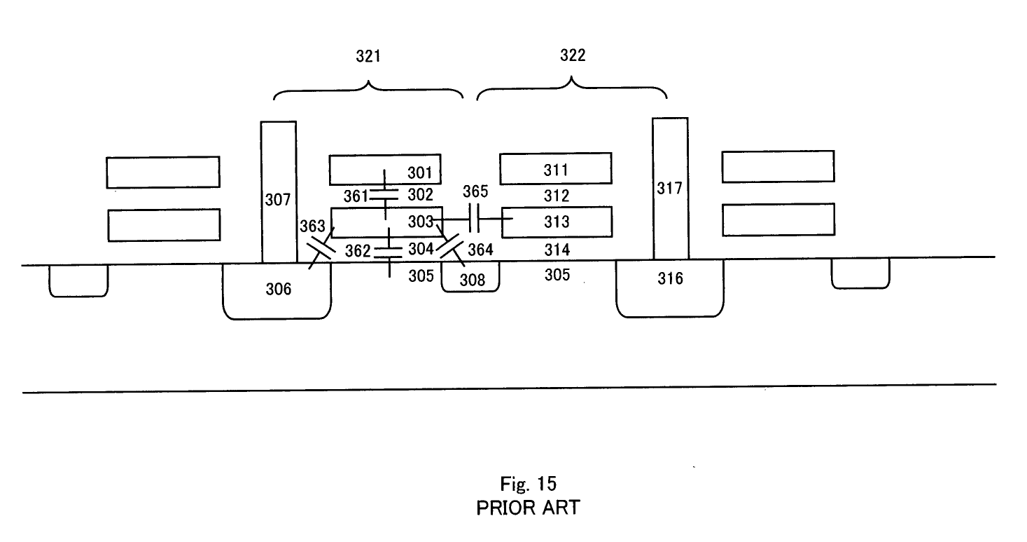

FIG. 16 is a sectional view of memory cell array structure of a semiconductor memory device according to the prior art;

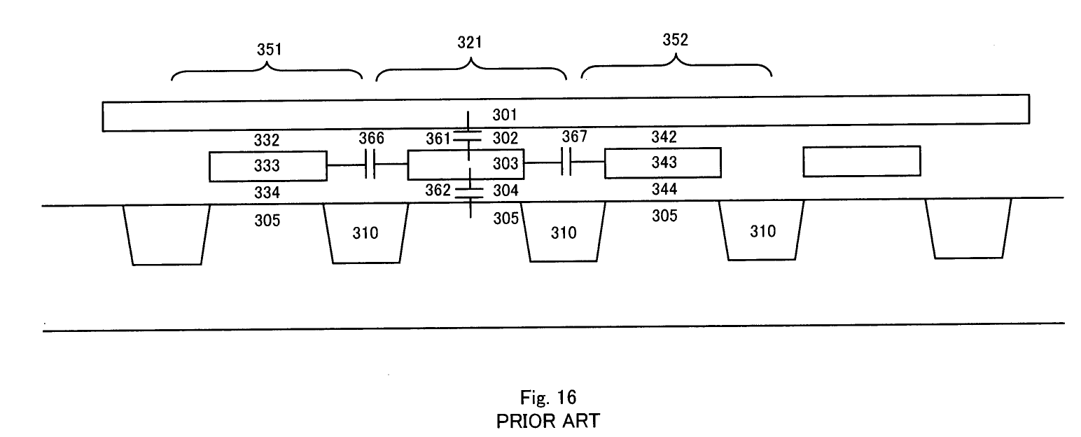

FIG. 17 is a block diagram showing configuration f a semiconductor memory device according to the prior art;

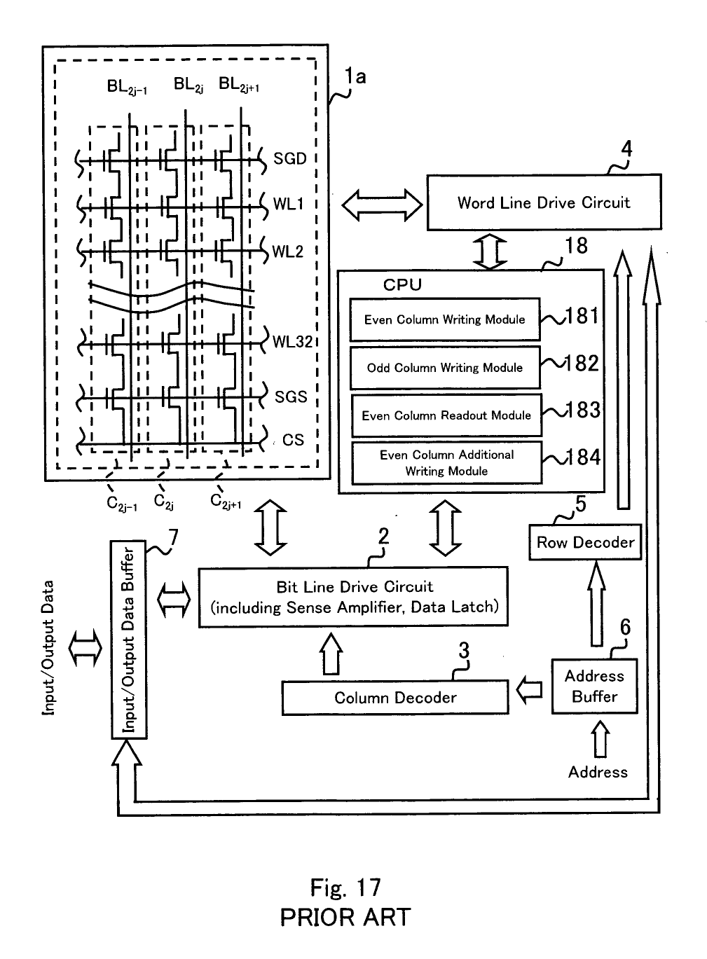

FIG. 18 is a distribution chart showing threshold voltage distribution in a method of writing to a semiconductor memory device according to the prior art;

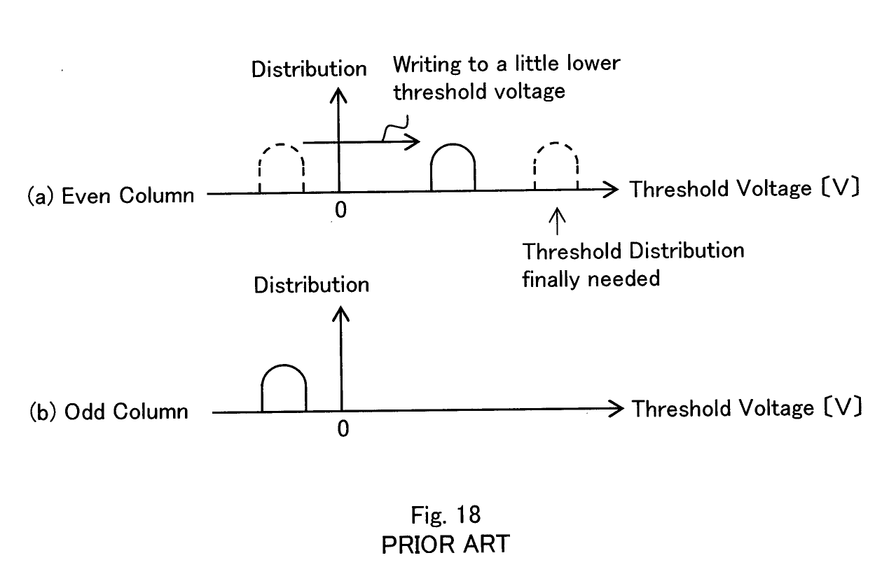

FIG. 19 is a distribution chart showing threshold voltage distribution in a method of writing to a semiconductor memory device according to the prior art; and

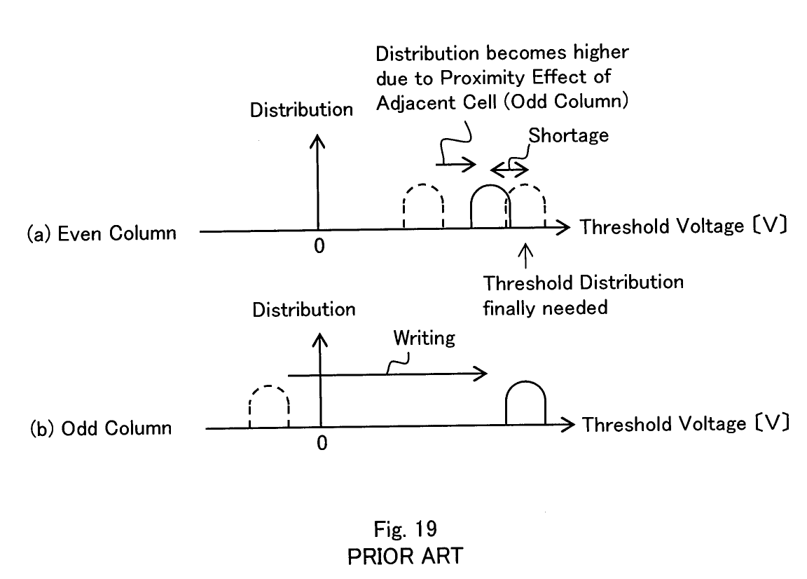

FIG. 20 is a distribution chart showing threshold voltage distribution in a method of writing to a nonvolatile semiconductor memory device according to the present invention.

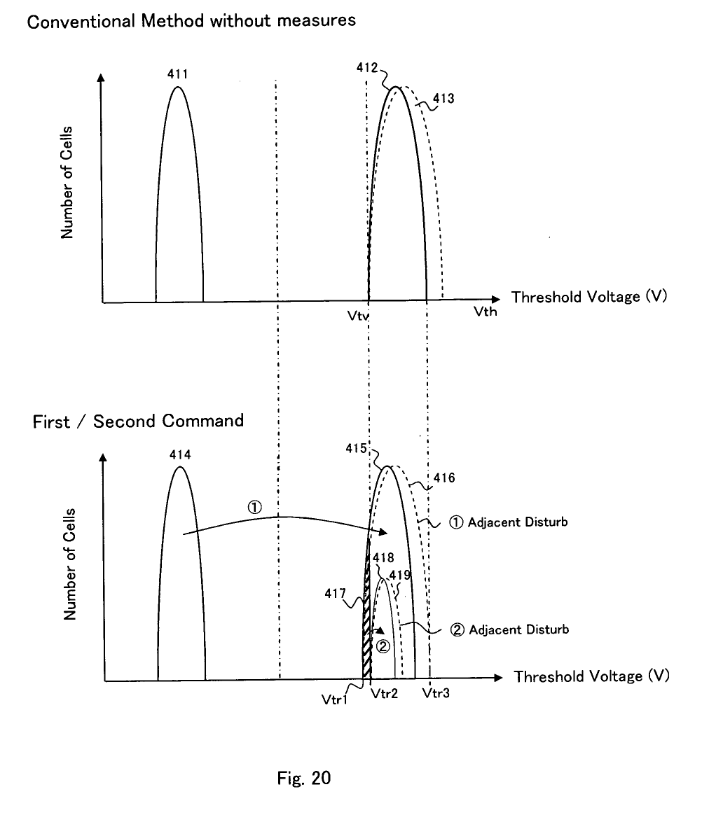

### DETAILED DESCRIPTION OF THE INVENTION

In the following, we describe embodiments of a nonvolatile semiconductor memory device according to the present invention and a method of writing thereto (hereinafter abbreviated as “a device of the present invention” and “a method of the present invention”, as appropriate), based on the drawings.

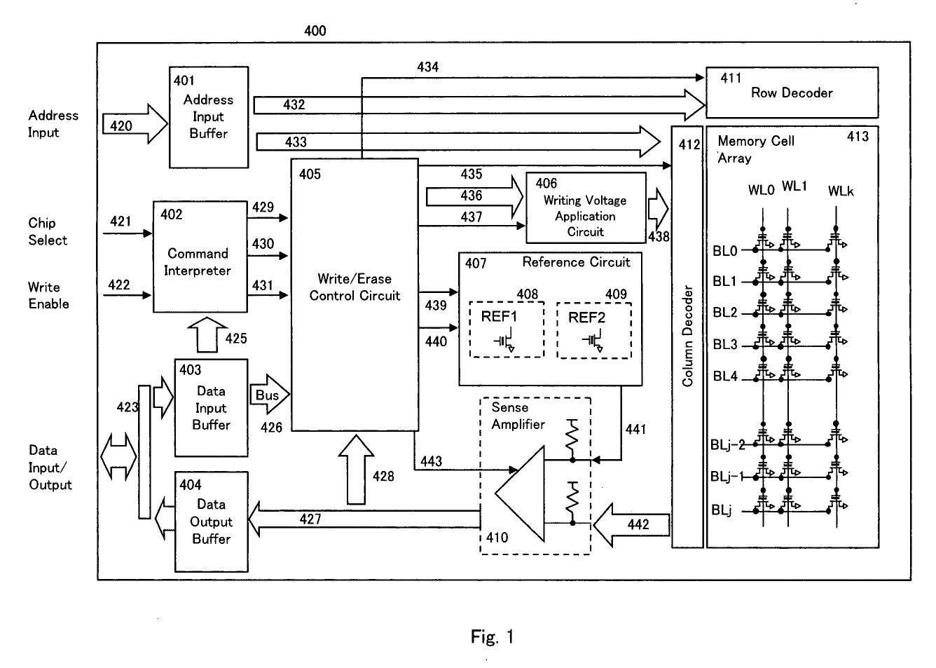

FIG. 1 is a circuit block diagram of one embodiment of a device of this invention 400. In this embodiment, it comprises memory cell arrays consisting of memory cells comprising nonvolatile transistors capable of electrically writing, erasing and reading out information arranged in a matrix in a row direction and in a column direction. As nonvolatile transistors comprising the memory cells, a floating gate type MOS transistor that has a floating gate, and is configured to perform writing by injecting channel hot electrons and erasing by using Fowler-Nordheim current (FN current) is used. In the memory cell array 413, bit lines BL0 to BLj and word lines WL0 to WLk are arranged, and the memory cells are respectively located at their intersections. Control gates of respective memory cells are connected to corresponding word lines, drains of respective memory cells are connected to corresponding bit lines, and sources of respective memory cells are commonly connecting to source lines (not shown). Voltage of the word lines WL0 to WLk is controlled by a row decoder 411 (corresponding to a column selection circuit) for selecting memory cells in the column direction, while voltage of the bit lines BL0 to BLj is controlled by a column decoder 412 (corresponding to a row selection circuit) for selecting memory cells in the row direction. During writing, the row decoder 411 applies sufficiently high voltage to perform hot electron writing to the word lines connected to the memory cells to which writing is performed, while it similarly applies sufficient voltage to conduct reading to the word lines during reading. During erasing, in order to generate FN current enough to erase memory cells, the row decoder 411 applies to the word lines voltage sufficiently lower than that of the bit lines or the substrate. During writing, the column decoder 412 supplies to the bit lines connected to the memory cells to which writing is performed high voltage generated at a writing voltage application circuit 406, while, during reading, it supplies current from current load of a sense amplifier 410 to the bit lines connected to memory cells to which readout is performed.

An address input buffer 401 receives address information from address input bus 402, and supplies addresses for selecting memory cells to the row decoder and column decoder, respectively, through internal address buses 432, 433. The row decoder 411 and column decoder 412 select word lines and bit lines corresponding to the internal address buses 432 and 433. Receiving data input from outside, a data input/output bus 423 not only transfers the data to a data input bus 403, but also outputs read data being transmitted from the sense amplifier 410 to outside through bus 427 and data output buffer 404.

When a command interpreter 402 recognizes that a chip select signal 421 and a light enable signal 422 have become active (“L” level signals, in general), it analyzes a value of data entered from inputted data bus 425. When a first external write command is executed, it activates a first write execution signal 429. When a second external write command is executed, it activates a second write execution signal 430. When an erase command is executed, it activates an erase execution signal 431.

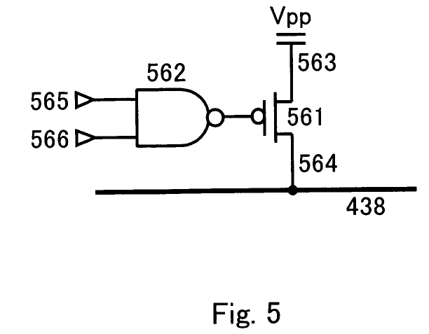

Aware that a first write execution signal 429, a second write execution signal 430, and an erase execution signal 431 from the command interpreter 402 have become active, a write/erase control circuit 405 (corresponding to the control circuit) automatically executes a write and erase algorithm. If the first write execution signal 429 or the second write execution signal 430 are active, it receives data to be written through bus 426 from data input buffer 403. When performing writing, it controls the row decoder 411, column decoder 412, write voltage application circuit 406, reference circuit 407, and the sense amplifier 443 by using control signals 434, 435, 437, 439, 440, 443. Although it also controls the respective circuits to erase, we herein omit the description thereof. In response to a write voltage application control signal 437 becoming active, the write voltage application circuit 406 supplies a write pulse signal 438 to the column decoder, corresponding to a value of writing data from the data bus 436. FIG. 5 shows one example of an actual circuit diagram of the write voltage application circuit 406. The write voltage application circuit 406 comprises a P type MOS transistor 561, a source of the P type MOS transistor 561 being connected to a high voltage signal 563, a drain 564 thereof being connected to bus 438 for supplying voltage to the column decoder 412, and a control gate thereof being connected to output of NAND circuit 562. Inputs 565 and 566 of the NAND circuit 562 are respectively connected to writing data 436 and writing voltage application control signal 437. When both the writing data 436 and the writing voltage application control signal 437 are active (“H”), the P type MOS transistor 561 turns on, and the writing pulse is supplied to the column decoder.

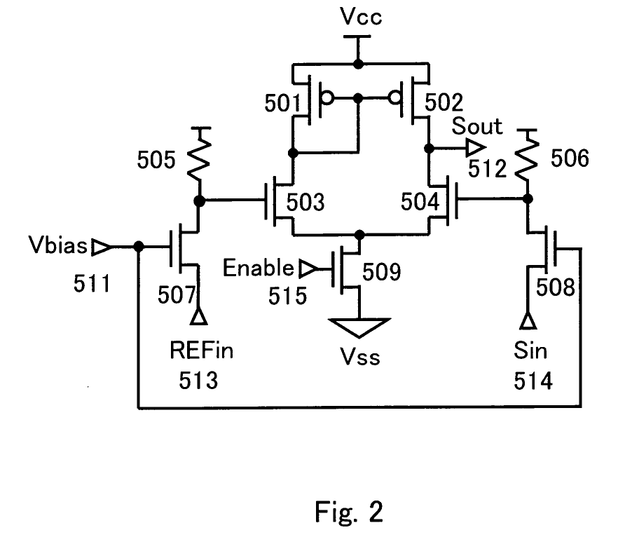

Based on a reference signal 441 from the reference circuit 407 and data from data bus 442, the sense amplifier 410 not only judges on memory cell information during readout, but also judges on whether writing has been adequately performed, or whether erasing has been adequately performed. In general, the operation is referred to verifying. Result of the verify operation is outputted to a write/erase control circuit 405 through buses 427, 428. FIG. 2 shows one example of the sense amplifier circuit. The MOS transistors 501 to 504, and 509 comprise a current mirror type sense amplifier, and comprises an enable signal 515 and output 512. Resistances 505, 506 are resistance loads for supplying readout current to the memory cells, sources 513, 514 of the MOS transistors 507, 508 are respectively connected to a reference cell of the reference circuit (FIG. 1, 407) and the memory cell (FIG. 1, 413), and the control gate 511 is connected to bias voltage Vbias. This could keep voltages of 513 and 514 at almost constant level, prevent a voltage higher than required from being applied to the memory cell in readout and convert memory cell current into voltage.

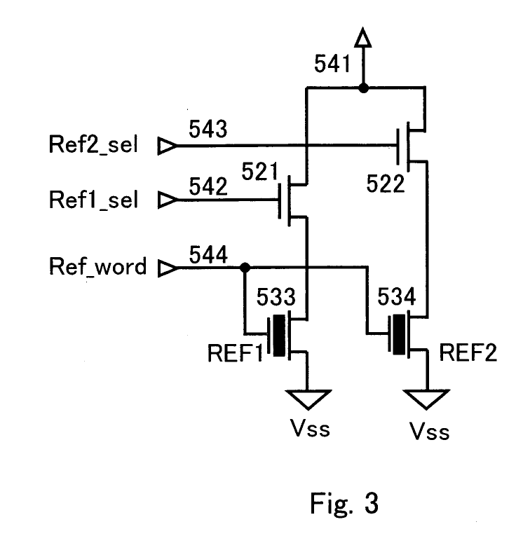

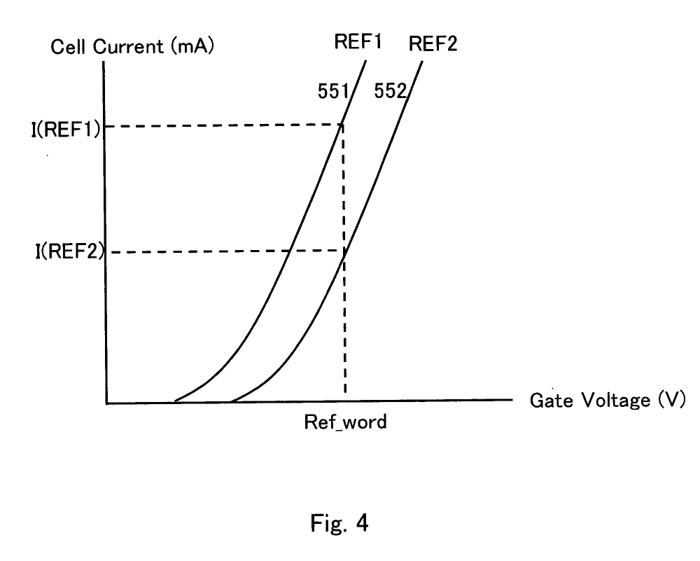

The reference circuit 407 comprises reference cells 408, 409 to be used in verifying at the write operations described above. Although the reference circuit 407 incorporates a reference cell to be used in verification during original erasing and a reference cell to be used in readout, we omit the description thereof. In the verify cycle when writing takes place by the first external write command, the control signal 439 is activated and the reference cell 408 is selected. In the verify cycle when writing takes place by the second external write command, the control signal 440 is activated and the reference cell 409 is selected. Now, FIG. 3 shows one example of configuration of the reference circuit 407. The nonvolatile memory cells 533, 534 of the floating gate type are reference cells REF1, REF 2, and are the same as the memory cells used in the memory cell array 413 of FIG. 1. In addition, MOS transistors 521, 522 are connected, and either reference cell REF1 or REF2 is selected by selection signals 542, 543. During verification, voltage necessary for verifying is applied to the control gate 544 for the reference cells REF1, REF2. Usually, the same voltage as that applied to the control gate of the memory cell to be verified is applied to the control gate 544 of the reference cells. The above mentioned sense amplifier 410 compares size of current flowing through these reference cells REF1 or REF2 with that of current flowing through the memory cells in the memory cell arrays 413 to be verified. FIG. 4 shows electrical properties 551, 552 (called as I-V curve) of the memory cells of the reference cells REF1, REF2, wherein the threshold voltage of the reference cell REF 1 is set to be slightly lower than that of the reference cell REF 2. The threshold voltage is usually set when a shipment test, and can be set to a predetermined value. As we described above, with this circuit, threshold voltage of memory cells can be written into the first threshold voltage (REF 1) when the first external write command is executed, while threshold voltage of memory cells can be written into the second threshold voltage (REF 2) when the second external write command is executed.

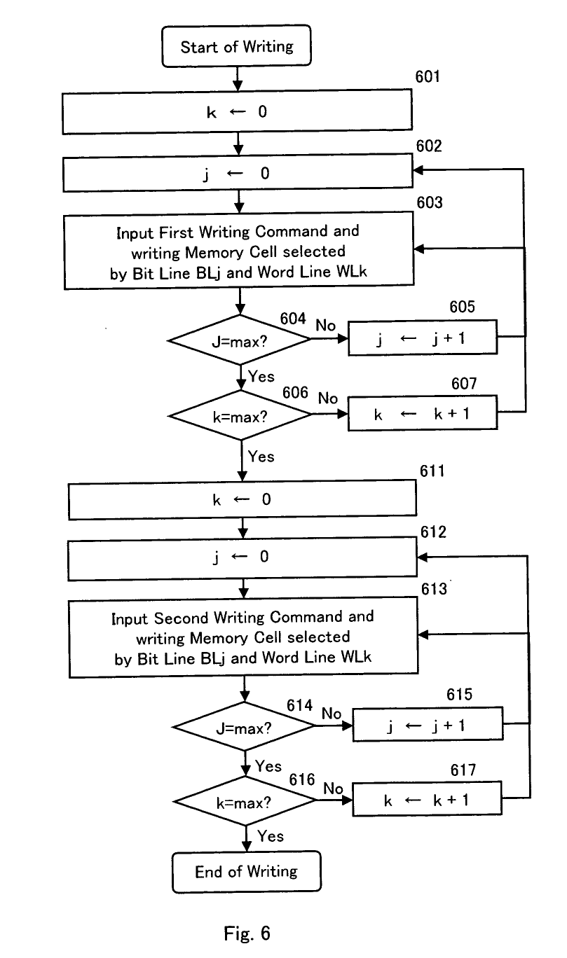

Now we have described configuration of the device of this invention 400 of the present embodiment. Next, we describe a writing algorithm of a method of the present invention, with reference to FIG. 6. This algorithm is controlled by a system such as PROM writer.

First, by setting k of the word line WLk to “0” (Step 601), and j of the bit line BLj to “0” (Step 602), select the memory cell at the intersection of the 0^{th} word line and the 0^{th} bit line. Then, a first external write command is entered into the device of this invention 400 (Step 603). When the first external write command is entered, the device of this invention 400 automatically writes to a first threshold voltage for the memory cell located at the intersection of the word line WL0 and bit line BL0. When writing is completed, the system verifies again whether j is the maximum value (Step 604). If it is not the maximum value (NO branch at Step 604), j is incremented by one (Step 605). A next bit line is selected by incrementing j, and the first write command is performed again to write to a next memory cell at Step 603. Step 603 is repeated until j becomes maximum (max). When j reaches the maximum (Yes branch at Step 604), continuously verify whether k is maximal (Step 606). If not (No branch at Step 606), k is incremented by 1 (Step 607), and a next word line is selected. At each word line, steps 603, 604, 605 are repeated until j reaches the maximum from 0. In addition, this operation (Steps 602 to 607) is repeated until k reaches the maximum. With this, writing is performed to all memory cells at the intersections of the word lines WL0 to k and the bit lines Bl0 to j by using the first external write command. Continuously, j and k are returned again to “0” and Steps 612 to 617 are repeated by using the second write command until j and k reach the maximum. With this, writing is performed to all memory cells at the intersections of the word lines WL0 to k and the bit lines BL0 to j by using the second write command.

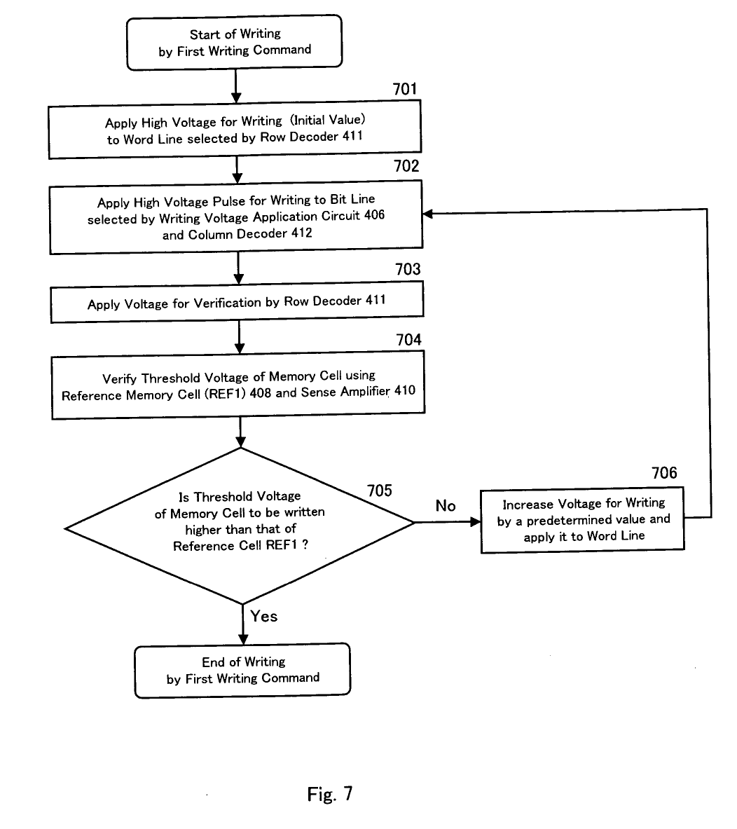

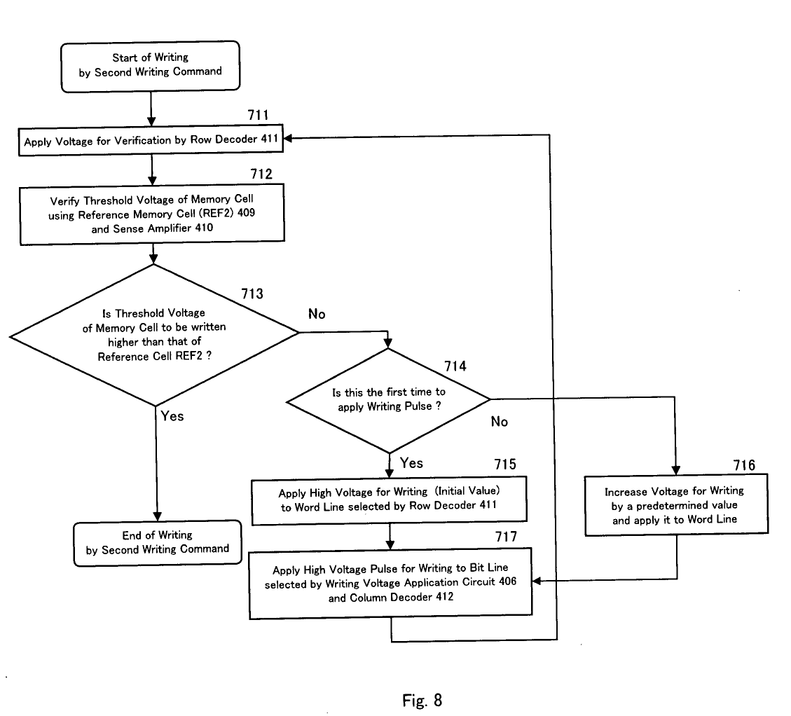

FIG. 7 and FIG. 8 further describe behavior of Steps 603 and 613 of FIG. 6, respectively, and illustrates an internal writing operation of a nonvolatile semiconductor device of this case. The internal writing operation is automatically performed by the write/erase control circuit 405 described above. When the first write command is executed at Step 603, first, an initial value of high voltage for writing is applied to the word line of the memory cell to which writing should take place (Step 701). Then, high voltage pulse is applied to the bit line of the memory cell that is a target of writing (Step 702). When application of high voltage pulse is completed, voltage for verification is applied to the word line of the memory cell that is a target of writing and the control gate of the reference cell REF 1 (Step 703). Then, the sense amplifier 410 is used to verify whether the threshold voltage of the memory cell that is a target of writing is higher than the threshold voltage of the reference cell REF 1 (408) (Step 704). If the threshold voltage of the memory cell that is a target of writing is not higher than the threshold voltage of the reference cell REF 1 (No branch at Step 705), voltage to be applied to the word line for writing is set slightly higher (Step 706). Then, writing pulse application and verify operation are performed again at Steps 702 to 705. This writing operation is repeatedly performed until the threshold voltage of the memory cell to which writing is performed goes beyond the threshold voltage of the reference cell REF 1.

Although in the writing operation as shown in FIG. 8, components are almost identical to those in FIG. 7, they differ in that the reference cell REF2 (409) is used during verify operation, and that the verify operation should be first performed immediately after writing begins. First, voltage for verification is applied to the word lines of the memory cell that is a target of writing and the control gate of the reference cell REF 2 (Step 711). Then, the sense amplifier 410 is used to verify whether the threshold voltage of the memory cell that is a target of writing is higher than that of the reference cell REF 2 (409) (Step 712). If the threshold voltage of the memory cell that is a target of writing is higher than that of the reference cell REF 2 (Yes branch at Step 713), writing terminates. If it has not reached the threshold voltage of the reference cell REF 2 (No branch at Step 713), writing pulse is applied (Steps 714 to 717). If it is the first time that the writing pulse is applied (Yes branch at Step 714), an initial value of high voltage for writing is applied to the word line of the memory cell that is a target of writing (Step 715), high voltage pulse for writing is applied to the bit line of the memory cell that is target of writing and writing is performed (Step 717). If it is the second time or later that high voltage for writing is applied (No branch at Step 714), voltage slightly higher than that used in application of the high voltage for last writing is applied to the word line (Step 716).

As we described in FIG. 1 and FIG. 4 as well, since the threshold voltage of the reference cell REF 1 is set slightly lower than that of the reference cell REF 2, first, in writing by using the first external write command, writing is performed to all memory cells at lower than the threshold voltage of the reference cell REF 2. Then, by using the second external write command, writing takes place at higher than the threshold voltage of the reference cell REF 2. When writing takes place by using the second external write command, effects on adjacent memory cells when writing is performed by the second external write command will be negligible, as the threshold voltage of the reference cell REF 2 does not differ so much from that of the reference cell REF 1.

As we described above, use of the device of the present invention 400 and the method of the present invention can not only completely prevent threshold voltage from increasing due to capacitive coupling from all adjacent memory cells, but also eliminate the need to prepare a data retention circuit for performing post-writing to the inside of the device of this invention, as a writing control is exercised by setting external commands, thereby enabling control of increased chip area.

### Alternative Embodiments

(1)

In the above embodiment, although the NOR type nonvolatile memory of floating gate structure is used, the NAND type nonvolatile memory may also be used. If memory cell arrays have the array structure in which writing to adjacent memory cells affects internal data of the memory cells, action can be taken by using the device of the present invention and the method of the present invention.

(2)

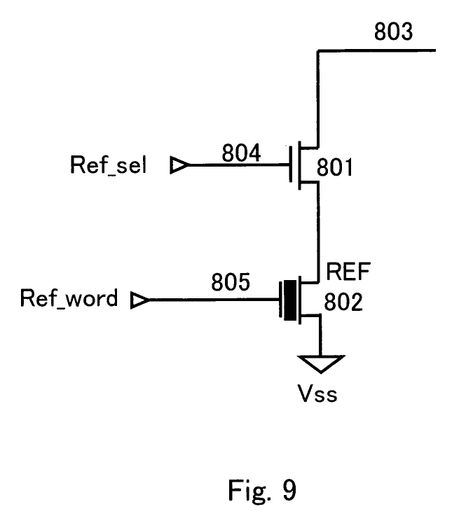

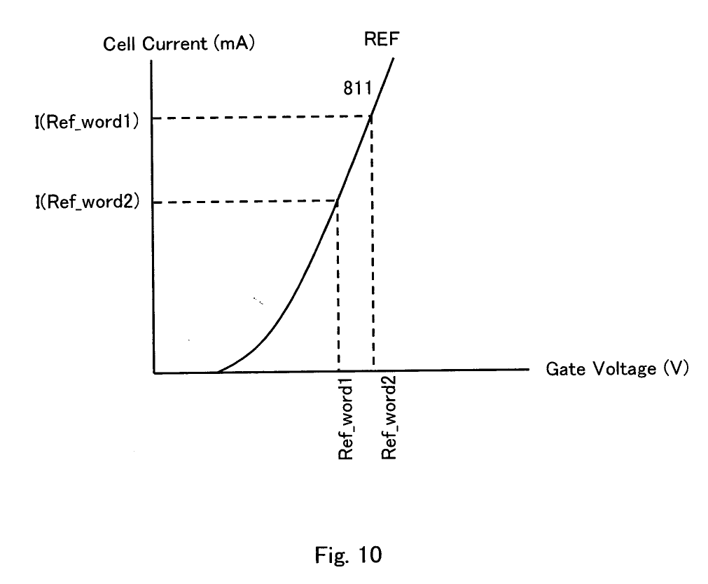

In addition, although general circuits such as those shown in FIG. 1, FIG. 2, FIG. 3, and FIG. 5 are used as internal circuits of the device of the present invention, they should not be limited to them, and the present invention can be implemented even with other circuits. For instance, as shown in FIG. 9 and FIG. 10, if only one reference cell 802 substitutes the reference cells REF 1, REF, 2, and internal verify voltage of when writing is performed with the first external write command and the second external write command is respectively changed to Ref_word1 and Ref_word2 as shown in FIG. 10, the similar effect can be achieved.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A nonvolatile semiconductor memory device comprising:
a memory cell array consisting of memory cells having a nonvolatile transistor capable of electrically writing, erasing and reading out information arranged in a matrix in a row direction and in a column direction; a row selection circuit for selecting the memory cell in the row direction; a column selection circuit for selecting the memory cell in the column direction; and a control circuit for exercising a writing control on the memory cell selected by the row selection circuit and the column selection circuit by a command inputted from outside, wherein
the control circuit is configured to be able to receive a first external write command and a second external write command, and performs a first threshold voltage control for writing the memory cell selected as a writing target to a first predetermined threshold voltage when receiving the first external write command, and a second threshold voltage control for writing the memory cell selected as a writing target to a second predetermined threshold voltage that is different from the first threshold voltage when receiving the second external write command.

2. The nonvolatile semiconductor memory device according to claim 1, wherein
the second threshold voltage is set within a predetermined range from a value derived from adding a variation of a threshold voltage to the first threshold voltage, and the variation of a threshold voltage is of the memory cell already written by the first threshold voltage control and caused by writing an adjacent memory cell.

3. The nonvolatile semiconductor memory device according to claim 1, wherein
the control circuit conducts the first threshold voltage control by applying a writing pulse based on a current comparison between the memory cell to be written and a first reference memory cell, and
the second threshold voltage control by applying a writing pulse based on a current comparison between the memory cell to be written and a second reference memory cell.

4. The nonvolatile semiconductor memory device according to claim 1, wherein
the control circuit conducts the first and second threshold voltage controls by using a same reference memory cell and applying different gate voltages between the first and second threshold voltage controls to a control gate of the memory cell or the reference memory cell.

5. A method of writing to the nonvolatile semiconductor memory device according to claim 1, the method comprising:
writing by the first external write command to a plurality of the memory cells selected as a writing target in the memory cell array; and
writing by the second external write command to the plurality of memory cells in the memory cell array written by the first external write command.

6. The method according to claim 5, wherein
an address and data of the memory cell to be written by the second external write command are the same as an address and data of the memory cell written by the first external write command.
